(19) United States
(12) Patent Application Publication
(10) Pub. No.: US 2009/0200572 A1
(43) Pub. Date: Aug. 13, 2009

(54) Lighting device and production method of the same

(76) Inventors: Hitoshi Kamamori, Chiba-shi (JP); Sadao Oku, Chiba-shi (JP)

Correspondence Address: BRUCE L. ADAMS, ESQ;ADAMS & WILKS, Suite 1231, 17 Battery Place, New York, NY, 10004, US

(21) Appl. No.: 12/322,692

(22) Filed: Feb. 5, 2009

(30) Foreign Application Priority Data
Feb. 8, 2008 (JP) 2008-028704
Jan. 30, 2009 (JP) 2009-020216

(51) Int. Cl. H01L 33/00; H01L 21/00

(52) U.S. Cl. 257/100; 438/26; 257/E21.001; 257/E33.059

(57) ABSTRACT

Bonding between a light-emitting element and electrodes of a substrate is ensured to enhance reliability of a lighting device. In the lighting device of the present invention, a material made of metal alkoxide or polymetalloxane generated from metal alkoxide is used as a coating material covering the light-emitting element. This may enhance reliability of the bonding between the substrate and the light-emitting element while keeping a high light-emission efficiency. Further, when a liquid material made of metal alkoxide is heat-cured by a sol-gel method, the liquid material changes from a liquid, a sol, a gel, to a solid successively to shrink, thereby generating glass being a solid material. With the use of a shrinking force obtained when the gel changes to the solid in the production method, the bonding between the light-emitting element and the electrodes of the substrate can be performed simultaneously with the curing of the coating material.

### BACKGROUND OF THE INVENTION

1. Field of the Invention

The present invention relates to a lighting device using a light-emitting element, and more particularly, to a lighting device in which bumps provided on a light-emitting element are bonded to electrodes provided in a package.

2. Description of the Related Art

Conventionally, as bonding methods for connecting electrodes of a light-emitting element to electrodes of a package in order to produce a lighting device, for example, wire bonding, die bonding, and flip-chip bonding are known.

FIG. 7A schematically illustrates a cross-sectional configuration of a lighting device in which electrodes are connected by wire bonding. As illustrated in FIG. 7A, a concave portion is formed on the upper surface of a substrate 63, and a light-emitting element 62 is bonded to the bottom surface of the concave portion with an adhesive 67. Electrodes 68 and 69 provided on the substrate 63 are placed apart on the bottom surface of the concave portion formed on the upper surface of the substrate 63 and on the lower surface of the substrate 63. The electrodes 68 and 69 and electrodes provided on the light-emitting element 62 are respectively connected by wire bonding, using wires 65 and 66. That is, the electrode 68 provided on the substrate 63 is electrically connected to the electrode provided on the light-emitting element 62 via the wire 65, and the electrode 69 is electrically connected to the electrode provided on the light-emitting element 62 via the wire 66. In FIG. 7A, the electrodes provided on the light-emitting element 62 are omitted (this also applies to FIGS. 7B and 7C described later). The concave portion of the substrate 63 is filled with a coating material 64 for covering the light-emitting element 62 and the wires 65 and 66.

For example, silver is used for the electrodes 68 and 69, and a high temperature-resistant resin made of a ceramic, a liquid crystal polymer, or the like is used for the substrate 63. Further, an epoxy resin excellent in light transmittance is used as the coating material 64.

FIG. 7B is a cross-sectional view schematically illustrating the configuration of a lighting device 72 in which electrodes are connected by wire bonding and die bonding. Die bonding is a process in which both the electrodes are directly bonded, for example, using a conductive adhesive 70 with silver particles mixed in an epoxy resin. Thus, only one connection terminal for wire bonding on the light-emitting element 72 suffices, which can enlarge an effective light-emitting area of the light-emitting element and improve a light-emission efficiency.

As illustrated in FIG. 7B, in the same way as in the light-emitting element 62 illustrated in FIG. 7A, the light-emitting element 72 is mounted on the bottom surface of the concave portion formed on the upper surface of the substrate 63. The electrodes 68 and 69 provided on the substrate 63 are placed apart on the bottom surface of the concave portion formed on the upper surface of the substrate 63 and on the lower surface of the substrate 63. The electrode 68 provided on the substrate 63 and the lower surface of the light-emitting element 72 are connected to each other with the conductive adhesive 70, and the electrode 69 and the upper surface of the light-emitting element 72 are bonded to each other by wire bonding using the wire 66. That is, the electrode 68 provided on the substrate 63 and the electrode provided on the lower surface of the light-emitting element 72 are directly connected to each other, and the electrode 69 and the electrode provided on the upper surface of the light-emitting element 72 are electrically connected to each other via the wire 66. The concave portion of the substrate 63 is filled with the coating material 64 so as to cover the wire 66. The configuration of the lighting device in which electrodes are connected by wire bonding and die bonding is disclosed by Patent Document 1, for example.

FIG. 7C is a cross-sectional view schematically illustrating the configuration of a lighting device in which electrodes are connected by flip-chip bonding. In flip-chip bonding, bumps in a protrusion shape are provided on a light-emitting element, and heat, a load, an ultrasonic wave, or the like is applied thereto, whereby the bumps are bonded to electrodes provided on a substrate. According to the flip-chip bonding, it is not necessary to use a connection terminal for wire bonding on a light-emitting element 82, which can further enlarge the effective light-emitting area of the light-emitting element and remarkably improve a light-emission efficiency. Further, a wire required in wire bonding is not necessary, which enables the reduction in thickness.

As illustrated in FIG. 7C, in the same way as in the light-emitting elements 62 and 72 described above, the light-emitting element 82 is mounted on the bottom surface of the concave portion formed on the upper surface of the substrate 63. The electrodes 68 and 69 provided on the substrate 63 are placed apart on the bottom surface of the concave portion formed on the upper surface of the substrate 63 and on the lower surface of the substrate 63. The electrodes 68 and 69 provided on the substrate 63 and the light-emitting element 82 are bonded to each other by flip-chip bonding. That is, the electrode 68 provided on the substrate 63 and the electrode provided on the light-emitting element 82 are electrically connected to each other via bumps 75, and the electrode 69 and the electrode provided on the light-emitting element 82 are electrically connected to each other via a bump 76. The concave portion of the substrate 63 is filled with the coating material 64 covering the light-emitting element 82. Further, gold can be exemplified as materials for the bumps 75 and 76 and the electrodes 68 and 69. The configuration of a lighting device in which electrodes are bonded by flip-chip bonding is disclosed by Patent Document 2, for example.

In the above-mentioned conventional lighting devices, the resin-based coating material 64 is used for covering the light-emitting element, and hence the resin-based coating material 64 may be degraded by the light emitted by and the heat generated by the light-emitting element, which may degrade the reliability as a lighting device.

Further, in the lighting device illustrated in FIG. 7A, the wires 65 and 66 are bonded to the electrodes 68 and 69 provided on the substrate 63 and the light-emitting element 62, which causes a problem that a mounting step is prolonged and a cost is increased. There is also a fear that the wires may be cut for some reasons. Further, wire bonding portions in which the wires are bonded to the electrodes and the light-emitting element are required to have further connection reliability. This also applies to the lighting device illustrated in FIG. 7B. Further, connection terminals for wire bonding are required on the light-emitting elements 62 and 72, which results in a small effective light-emitting area of the light-emitting element.

Further, in the lighting device illustrated in FIG. 7C, a terminal for wire bonding is not required on the light-emitting element 82, and hence there is an advantage of a large effective light-emitting area of the light-emitting element. However, the bumps provided on the light-emitting element 82 and the electrodes provide on the substrate 63 are bonded to each other by flip-chip bonding, and hence the electrical connection therebetween may become unstable due to the heat generated by the light-emitting element 82, which may decrease the reliability as a lighting device.

### SUMMARY OF THE INVENTION

It is an object of the present invention to ensure the bonding between electrodes provided on a substrate and electrodes or bumps provided on a light-emitting element while keeping a light-emission efficiency equal to that of flip-chip bonding, thereby enhancing reliability as a lighting device.

In order to solve the above-mentioned problems, in the present invention, a solid material obtained by curing a raw material containing metal alkoxide or polymetalloxane is used as a coating material provided so as to protect a mounting portion in a lighting device in which a light-emitting element is mounted on electrodes formed on a substrate using a conductive member. Further, a concave portion is formed on the substrate, and the light-emitting elements are placed on a bottom surface of the concave portion, whereby the concave portion is filled with the coating material.

Further, the coating material is also placed in a gap between the substrate and the light-emitting element, and bonding between the conductive member and at least one of the electrode of the substrate and the electrode of the light-emitting element is kept by shrinking occurring when the raw material of the coating material is cured.

Further, as the coating material, a solid material is used, which is obtained by subjecting metal alkoxide and water to hydrolysis and a polycondensation reaction by a sol-gel method, and changing the resultant by heat curing.

Further, the gap between the light-emitting element and the substrate includes an insulating adhesive with elasticity in a part thereof, and the coating material is placed in a portion without the insulating adhesive.

Further, the substrate includes a stopper formed thereon for positioning the light-emitting element at a predetermined place.

Further, a lighting device in which a light-emitting element is electrically connected to an electrode formed on a substrate using a conductive member is manufactured through the following steps. That is, the method includes: a first step of positioning the electrode of the substrate and the electrode of the light-emitting element each other, and fixing the light-emitting element to the substrate; a second step of supplying a coating material containing one of metal alkoxide and polymetalloxane to a gap between the light-emitting element and the substrate; and a third step of curing the coating material to generate a solid coating material, in which bonding between the conductive member and at least one of the electrode of the substrate and the electrode of the light-emitting element is kept by shrinking occurring when the coating material is cured.

The third step includes curing polymetalloxane generated from metal alkoxide to generate a solid coating material.

Further, the third step includes further polycondensing and heat-curing polymetalloxane obtained by hydrolyzing and polycondensing metal alkoxide and water to generate a solid coating material.

Further, the present invention includes the step of forming a concave portion for mounting a light-emitting element on a substrate, and the second step includes supplying the coating material containing metal alkoxide to the concave portion to cover the light-emitting element.

Further, the first step includes firmly fixing the light-emitting element to the substrate with an insulating adhesive with elasticity. This prevents a movement of the light-emitting element due to the supply of the coating material.

Further, the production method for a lighting device includes a step of forming a stopper for positioning the light-emitting element at a predetermined place on the substrate, in which the first step includes positioning the light-emitting element to be fixed on the substrate by the stopper.

According to the lighting device of the present invention, the reliability of bonding between the substrate and the light-emitting element can be enhanced while a high light-emission efficiency is ensured.

Further, according to the production method of the present invention, the coating material is allowed to shrink, whereby the bumps provided on the light-emitting element and the electrodes on the substrate are bonded to each other. This makes it unnecessary to use a wire and an adhesive for the bonding therebetween, and shortens the mounting step of a lighting device. Further, a force of pulling the light-emitting element on an upper surface of the substrate opposed to the lower surface of the light-emitting element is generated by allowing the coating material to shrink. This can ensure the bonding between the bumps provided on the light-emitting element and the electrodes provided on the substrate, and enhance the reliability of electrical connection. Thus, the reliability as a lighting device can be enhanced. Further, a connection terminal for wire bonding on a light-emitting element is not required, and hence a light-emission efficiency equal to that of flip-chip bonding can be ensured.

### BRIEF DESCRIPTION OF THE DRAWINGS

In the accompanying drawings:

FIG. 1 is a cross-sectional view illustrating a configuration of a lighting device according to Embodiment 1 of the present invention;

FIG. 2 is a cross-sectional view illustrating a configuration of a lighting device according to Embodiment 2 of the present invention;

FIG. 3 is a cross-sectional view illustrating a bonding principle between bumps and electrodes;

FIG. 4 is a cross-sectional view schematically illustrating a configuration of a lighting device of the present invention;

FIG. 5 is a flow diagram illustrating a production method for a lighting device according to the present invention;

FIG. 6 is a flow diagram illustrating a sol-gel method; and

FIG. 7 is a cross-sectional view schematically illustrating a configuration of a conventional lighting device.

### DETAILED DESCRIPTION OF THE PREFERRED EMBODIMENTS

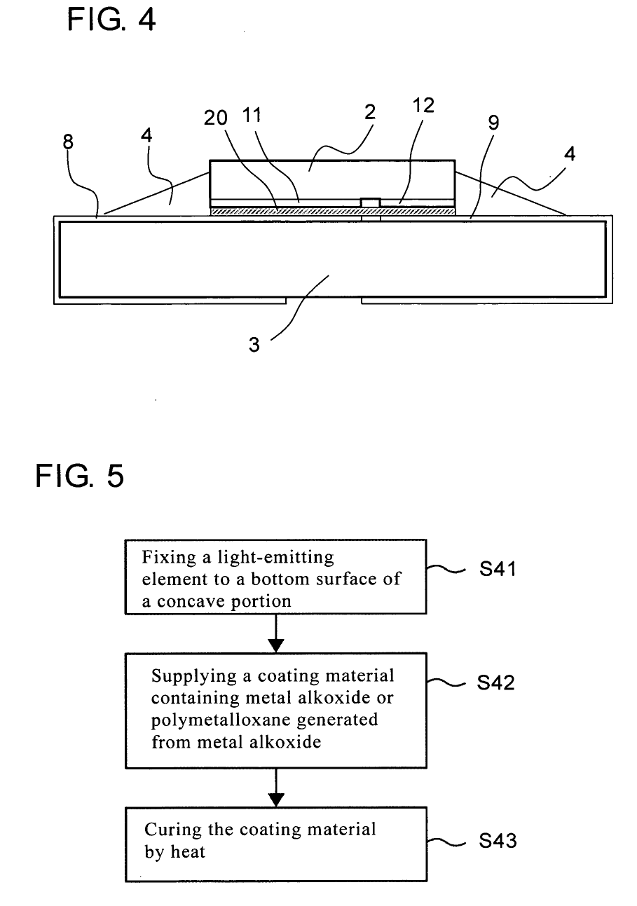

FIG. 4 schematically illustrates a lighting device of the present invention. As illustrated in FIG. 4, the lighting device has a configuration in which a light-emitting element 2 is mounted on a substrate 3. The light-emitting element 2 includes electrodes 11 and 12, and emits light when the electrodes 11 and 12 are supplied with a voltage. The electrodes 11 and 12 of the light-emitting element 2 are electrically connected to electrodes 8 and 9 formed on the substrate 3 with a conductive member 20. The electrodes 8 and 9 formed on the substrate 3 are patterned wiring, and can be led out electrically from the reverse side of the substrate 3. In order to protect the connection between the light-emitting element 2 and the substrate 3, a coating material 4 is provided around the light-emitting element 2. The coating material 4 can also be provided so as to cover the light-emitting element 2 mounted on the substrate 3. Then, as the coating material 4, a solid material obtained by curing a raw material containing metal alkoxide or polymetalloxane is used. When a liquid material made of metal alkoxide is heat-cured by a sol-gel method, the liquid material changes and shrinks in order from a liquid, a sol, a gel, to a solid successively to obtain glass that is a solid material. Polymetalloxane corresponds to the sol state. Thus, the coating material 4 can also be referred to as a solid material obtained by curing polymetalloxane generated from metal alkoxide.

Thus, in the case where the substrate 3 is made of glass, the adhesion between the coating material 4 and the substrate 3 is enhanced. This is because both the substrate and the coating material are made of glass. Further, when a concave portion is provided on the substrate, a light-emitting element is placed on the bottom surface of the concave portion, and the concave portion is filled with the coating material, the reliability is further enhanced. Further, electrodes to be formed on the substrate may be a through electrode passing through the substrate as well as a thin film electrode formed on the substrate. Embodiments of the conductive member include an isotropic conductive adhesive and bumps.

Further, in order to bond the light-emitting element to the substrate, a coating material containing metal alkoxide or polymetalloxane generated from metal alkoxide is supplied even in a gap between the light-emitting element and the substrate. When a liquid material made of metal alkoxide is heat-cured by a sol-gel method, the liquid material changes and shrinks in order from a liquid, a sol, a gel, to a solid successively, whereby glass that is a solid material is generated. Polymetalloxane corresponds to the sol state. The present invention is based on the fact that there is a large volume reduction while a polymetalloxane sol becomes a wet gel by polycondensation, and finally becomes a solid through a dry gel by heating, and achieves the bonding between a light-emitting element and a substrate utilizing the shrinking force generated while the volume of the sol decreases. The shrinking force generated when the gel changes to a solid is utilized for the production method, whereby the bonding between the light-emitting element and the electrodes of the substrate can be performed simultaneously with the curing of the coating material.

Specifically, a light-emitting element is placed on a substrate with electrodes formed thereon, and a gap between the light-emitting element and the substrate is filled with a material made of metal alkoxide or polymetalloxane generated from metal alkoxide. As a method of supplying this material, any method can be used as long as it can fill the material in the gap, and examples thereof include potting (dropping) and coating to a peripheral portion. The material may be supplied under a reduced pressure in order to fill the gap with the material exactly. The amount of the material filling at least the gap suffices, but when the material is supplied so as to cover the light-emitting element, the bonding strength may be enhanced. Then, the material is heat-cured to generate glass that is a solid material. The glass that is a solid material fixes the light-emitting element and the substrate. More specifically, the solid material keeps the bonding between at least one of the electrode of the substrate and the electrode of the light-emitting element, and the conductive member. Further, a sealing agent generally used may be provided so as to cover the solid material (solidified coating material).

Polymetalloxane generated from metal alkoxide shrinks when being heat-cured. Therefore, a force directed from the lower surface of the light-emitting element to the surface of the substrate, i.e., the force of pulling the light-emitting element is generated with the surface of the substrate on which the light-emitting element is mounted being a reference. This ensures the bonding between the electrodes provided on the substrate or the light-emitting element and the conductive member, thereby enhancing the reliability of electrical connection and the reliability as a lighting device.

Further, a concave portion may be provided on the substrate. More specifically, the light-emitting element may be placed on the concave portion, a material made of metal alkoxide or polymetalloxane generated from metal alkoxide is supplied to the concave portion, and the gap between the surface of the concave portion and the light-emitting element may be filled with the material. Then, the material is heat-cured to generate glass that is a solid material. The glass that is a solid material becomes a coating material. At this time, the concave portion may be filled with only the solid material, or a solid material may be formed so as to cover the light-emitting element, and thereafter, a general sealing material may be supplied onto the solid material.

Further, the above-mentioned configuration can also be applied to a configuration in which bumps used as a conductive member are formed on electrodes of the light-emitting element.

According to the above-mentioned configuration, the bonding conducted between the electrodes of the light-emitting element and the electrodes of the substrate via a conductive member is ensured, which can enhance the reliability of electrical connection and the reliability as a lighting device. Hereinafter, more detailed embodiments are described.

### Embodiment 1

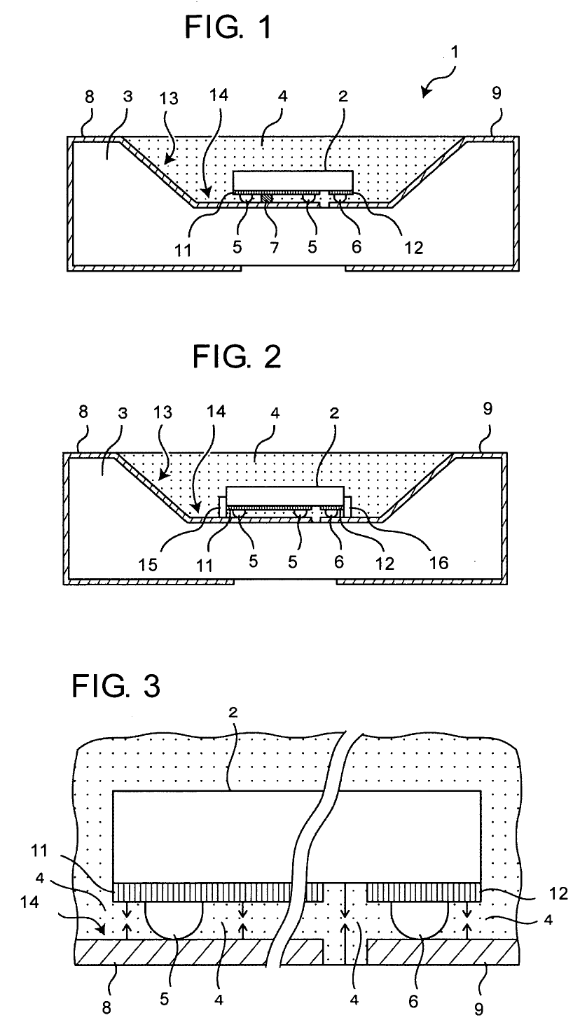

FIG. 1 schematically illustrates a cross-sectional configuration of a lighting device 1 of Embodiment 1. As illustrated in FIG. 1, a light-emitting element 2 having electrodes 11 and 12 is mounted on a bottom surface 14 of a concave portion formed on the upper surface of a substrate 3 having electrodes 8 and 9. The electrodes 8 and 9 are made of a wiring material and placed apart on the bottom surface 14 of the concave portion and the lower surface of the substrate 3. An adhesive 7 is provided between the light-emitting element 2 and the substrate 3 so that the mounting position of the light-emitting element 2 is not displaced easily. Bumps 5 and 6 are provided between the electrodes of the light-emitting element 2 and the electrodes of the substrate 3. Further, the concave portion of the substrate 3 is supplied with a coating material 4 so that the coating material 4 covers the light-emitting element 2.

Light emitted from the upper surface and side surface of the light emitting element 2 is radiated directly outside through the coating material 4, or is reflected by an inclined surface 13 or the bottom surface 14 of the concave portion formed on the substrate 3 through the coating material 4 to be radiated outside. On the bottom surface of the light-emitting element 2, a p-type electrode 11 and an n-type electrode 12 are provided, and the bumps 5 and the bump 6 are provided respectively on the lower surface of the electrode 11 and the lower surface of the electrode 12.

In FIG. 1, two bumps are provided on the lower surface of the p-type electrode 11 and one bump is provided on the lower surface of the n-type electrode 12, but the number of the bumps is not limited in the present invention and the provision of at least one bump suffices.

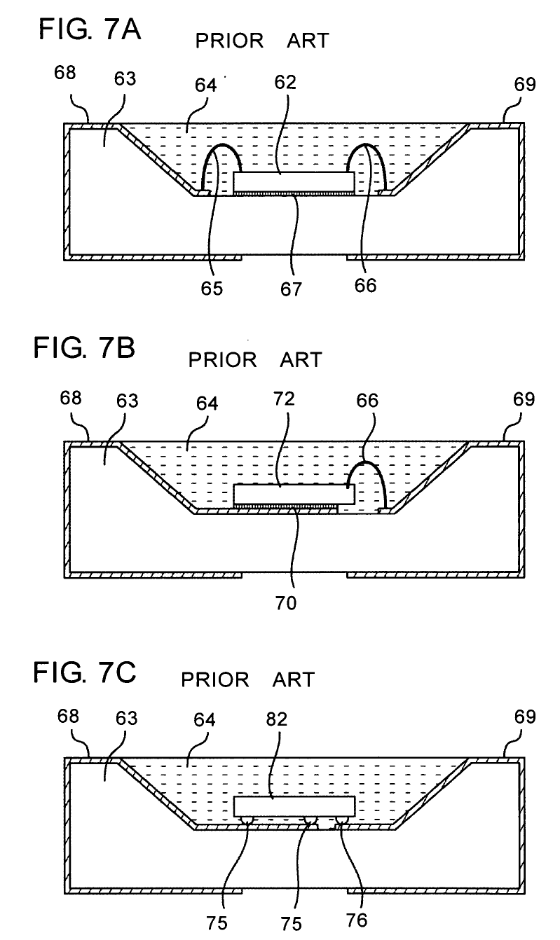

The light-emitting element 2 is, for example, an LED element, and as the material thereof, for example, a semiconductor material such as AlGaAs is used. As the bumps 5 and 6, for example, Au is used in the same way as in the bumps 75 and 76 illustrated in FIG. 7c.

Here, the electrode on the bottom surface 14 of the concave portion of the substrate 3 and the bumps provided on the light-emitting element 2 are bonded to each other by a new procedure utilizing the property of the coating material 4 of shrinking by a sol-gel method. The detail of the new procedure is described later. Then, the electrode 8 provided on the substrate 3 and the electrode 11 provided on the light-emitting element 2 are electrically connected to each other with the bumps 5, and the electrode 9 and the electrode 12 are electrically connected with the bump 6.

For example, a high temperature-resistant resin made of a ceramic, a liquid crystal polymer, or the like is used for the substrate 3 in the same way as in the substrate 63 illustrated in FIGS. 7A to 7C. The electrodes 8 and 9 are desirably made of silver with a high reflectance so as to reflect light emitted from the light-emitting element. However, gold can also be used for the electrodes 8 and 9 in the same way as in the electrodes 68 and 69 illustrated in FIG. 7C. Further, the concave portion formed on the substrate 3 has a substantially circular mortar shape when viewed from above and decreases in a diameter downward, and the diameter of the bottom surface 14 is minimum.

The adhesive 7 is an insulating adhesive with elasticity, which bonds the electrode 8 provided on the substrate 3 to the electrode 11 provided on the light-emitting element 2 and fixes the light-emitting element 2 to the bottom surface 14 of the concave portion of the substrate 3. The adhesion area of the adhesive 7 is assumed to be sufficiently smaller than that of the lower surface of the light-emitting element 2.

With the use of the adhesive 7, even if a liquid material made of metal alkoxide is applied to the concave portion formed on the substrate 3, the light-emitting element 2 can maintain the fixed state without moving on the bottom surface 14 of the concave portion formed on the substrate 3. Further, even when a liquid material made of metal alkoxide is heat-cured to shrink, the light-emitting element 2 does not move in a direction parallel to the bottom surface 14 of the concave portion formed on the substrate 3. In this case, along with the shrinking of the liquid material made of metal alkoxide, the light-emitting element 2 moves in a downward direction orthogonal to the lower surface (in a direction toward the bottom surface 14 of the concave portion formed on the substrate 3) until the bumps 5 come into contact with the electrode 8 and the bump 6 comes into contact with the electrode 9, due to the shrinking of the adhesive 7 caused by the elasticity of the adhesive 7.

The coating material 4 is glass generated by heat-curing the liquid material made of metal alkoxide by a sol-gel method. When heated, polymetalloxane generated from metal alkoxide shrinks to generate solid glass finally. The detailed description of the principle of bonding a bump and an electrode utilizing the shrinking property, and the detailed description of a sol-gel method are described later.

### Embodiment 2

FIG. 2 schematically illustrates a cross-sectional configuration of a lighting device of Embodiment 2. As illustrated in FIG. 2, stoppers 15 and 16 for fixing the light-emitting element 2 are formed on the substrate 3.

The lighting device 1 according to Embodiment 1 illustrated in FIG. 1 and a lighting device according to Embodiment 2 are identical in that both of them include the light-emitting element 2 with the electrodes 11 and 12 and the bumps 5 and 6, the substrate 3 with the electrodes 8 and 9, and the coating material 4 covering the light-emitting element 2. On the other hand, the adhesive 7 is provided so as to fix the light-emitting element 2 to the substrate 3 in Embodiment 1, whereas the stoppers 15 and 16 are provided in place of the adhesive 7 in Embodiment 2.

The stoppers 15 and 16 are protrusions in a convex shape provided on the bottom surface 14 of the concave portion formed on the substrate 3, and sandwich the light-emitting element 2 in order to prevent the light-emitting element 2 from moving on the bottom surface 14 of the concave portion to cause a displacement between the bumps 5 and 6 and the electrodes 8 and 9. The bumps provided on the light-emitting element 2 and the electrodes of the substrate 3 are in contact. That is, the stoppers 15 and 16 are provided so as to fix the light-emitting element 2 on the bottom surface 14 of the concave portion formed on the substrate 3.

In FIG. 2, two stoppers 15 and 16 are provided so as to sandwich the light-emitting element 2, but the number of the stoppers and the shape thereof are not limited in the present invention, and any number of the stoppers in any shape can be used as long as they can fix the light-emitting element 2 to the bottom surface 14 of the substrate 3. The shape of the stoppers may be a cylindrical shape or a prismatic shape.

Accordingly, with the use of the stoppers, the light-emitting element 2 does not move on the bottom surface 14 of the substrate 3 even if a liquid material made of metal alkoxide is applied to the concave portion formed on the substrate 3, and can keep a fixed state. Further, even if the liquid material made of metal alkoxide is heat-cured to shrink, the light-emitting element 2 does not move on the bottom surface 14 of the substrate 3 to cause the displacement between the bumps 5 and 6 and the electrodes 8 and 9.

### (Bonding Between Bumps and Electrodes)

Next, the description is made of the principle of bonding the bumps 5 and 6 to the electrodes 8 and 9 by heat-curing the coating material 4 of a liquid material made of metal alkoxide or polymetalloxane generated from metal alkoxide to allow the coating material 4 to shrink. FIG. 3 is a cross-sectional view illustrating the principle of bonding the bumps 5 and 6 provided on the light-emitting element 2 to the electrodes 8 and 9 provided on the substrate 3, which illustrates the cross-sectional views illustrated in FIGS. 1 and 2 in a partially enlarged state.

When the coating material 4 of a liquid material made of metal alkoxide or polymetalloxane generated from metal alkoxide is applied to the concave portion formed on the substrate 3, the light-emitting element 2 is covered with the coating material 4. In this case, the space between the lower surface of the light-emitting element 2 and the bottom surface 14 of the concave portion opposed to the lower surface is also filled with the coating material 4 without any space.

Then, when the coating material 4 is heat-cured to shrink, a force indicated by arrows as illustrated in FIG. 3, i.e., a force at which the lower surface of the light-emitting element 2 and the bottom surface 14 of the concave portion attract each other (force of pulling the lower surface of the light-emitting element 2 with the bottom surface 14 of the concave portion being a reference plane) is generated. The reason for this is as follows: the coating material 4 is exposed on the upper surface of the concave portion formed on the substrate 3, and hence the shrinking force thereof acts on the bottom surface 14 of the concave portion formed on the substrate 3; that is, the shrinking force of the coating material 4 acts on the bottom surface 14 of the concave portion formed on the substrate 3 so as to pull the light-emitting element 2.

Thus, the coating material 4 shrinks to generate the force indicated by the arrows as illustrated in FIG. 3, whereby the bumps provided on the light-emitting element 2 and the electrodes provided on the substrate 3 attract each other. This can ensure the bonding therebetween and enhance the reliability of electrical connection. This enables the enhancement of the reliability as a lighting device.

### (Production Method)

Next, a production method for a lighting device in which electrodes are connected using a sol-gel method is described. FIG. 5 is a flow diagram illustrating a method of producing lighting devices in Embodiments 1 and 2. Here, the step of providing the electrodes 11 and 12 and the bumps 5 and 6 on the light-emitting element 2, the step of forming the concave portion in the substrate 3, and the step of providing the electrodes 8 and 9 are omitted. It is assumed that the coating material 4 of a liquid material made of metal alkoxide or polymetalloxane generated from metal alkoxide, the adhesive 7 in Embodiment 1, and the stoppers 15 and 16 in Embodiment 2 are previously prepared. All the steps in the production method are performed using a production apparatus.

First, the light-emitting element 2 is fixed to the bottom surface 14 of the concave portion formed on the substrate 3 in Step S41. Specifically, the light-emitting element 2 is fixed using the adhesive 7 in Embodiment 1 and using the stoppers 15 and 16 in Embodiment 2 so that the light-emitting element 2 does not move in the subsequent steps.

Then, the coating material 4 of a liquid material made of metal alkoxide is supplied to the concave portion formed on the substrate 3 to cover the light-emitting element 2 (Step S42). In this case, it is necessary that the coating material 4 of a liquid material should be applied sufficiently so that the light-emitting element 2 is covered with the coating material 4 in a solid form even when the coating material 4 of a liquid material shrinks to generate the coating material 4 in a solid form in Step S43 described later. Further, when the coating material of a liquid material is supplied under a reduced pressure, there is an effect that space between the substrate and the light-emitting element can also be filled with the coating material easily and exactly.

Then, the coating material 4 of a liquid material made of metal alkoxide or polymetalloxane generated from metal alkoxide is heat-cured (Step S43). Due to the heat-curing, the liquid material gradually decreases in volume to generate glass that is the coating material 4 in a solid form through a gel state. This ensures the bonding between the bumps provided on the light-emitting element 2 and the electrodes provided on the substrate 3.

### (Sol-Gel Method)

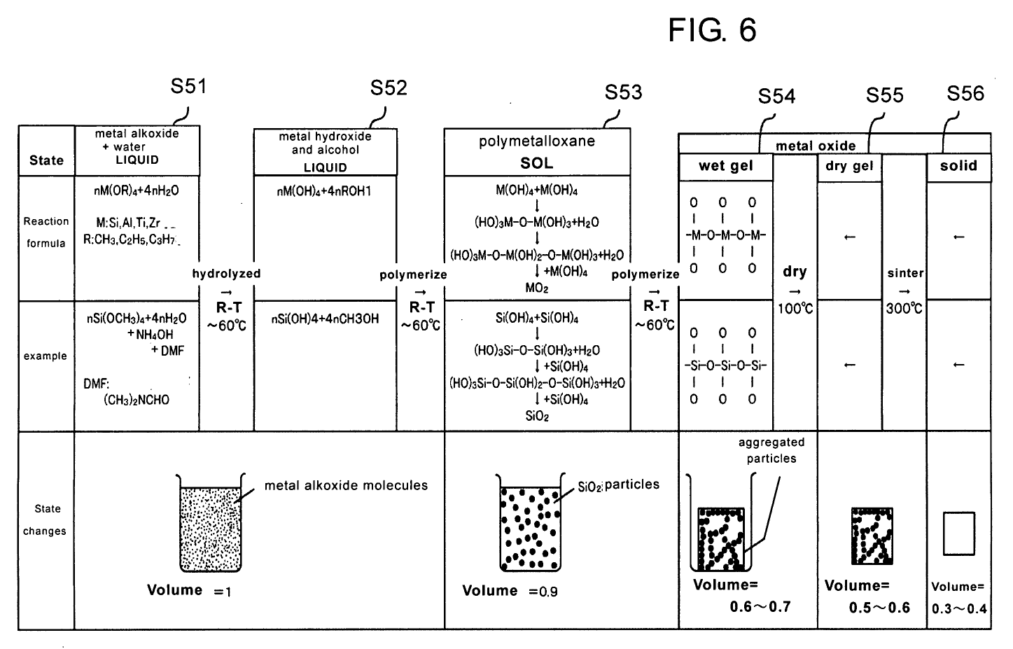

Next, a sol-gel method in Step S43 illustrated in FIG. 5 is described in detail. FIG. 6 is a flow diagram illustrating the sol-gel method. The flow diagram illustrates a series of state changes in which the coating material of a liquid material made of metal alkoxide changes to generate glass that is a coating material in a solid form.

First, water is added to metal alkoxide to generate a liquid material made of metal alkoxide (Step S51). The reaction formula is nM (OR)₄+4nH₂O as illustrated in a column of the reaction formula in Step S51 of FIG. 6. Here, M is Si or the like, and R is CH₃ or the like. The example uses NH₄OH as a catalyst and DMF as a crack preventive, respectively, as illustrated in a column of the example in Step 51 of FIG. 6. DMF is dimethylformamide ((CH₃)₂NCHO).

When the liquid is hydrolyzed at room temperature to 60° C. in Step S51, a metal hydroxide and alcohol are generated (Step S52). The reaction formula is nM(OH)₄+4nROH⇑ as illustrated in a column of the reaction formula in Step S52 of FIG. 6. The example is nSi(OH)₄+4nCH₃OH as illustrated in a column of the example in Step S52 of FIG. 6.

When the liquid is polymerized at room temperature to 60° C. in Step S52, a sol-shaped polymetalloxane is generated (Step S53). The reaction formula and example are as illustrated in a column of the reaction formula and a column of the example in Step S53 of FIG. 6, respectively.

Here, assuming that the volume of the liquid made of metal alkoxide molecules in Steps S51 and S52 is 1, the volume of a sol made of SiO₂ particles in Step S53 is 0.9, and the coating material 4 shrinks from a liquid to a sol along with the change in state.

When the sol is polymerized at room temperature to 60° C. in Step S53, a metal oxide in a wet gel form is generated (Step S54). The reaction formula and example are as illustrated in a column of the reaction formula and a column of the example in Step S54 of FIG. 6, respectively.

Here, the volume of the wet gel made of aggregated particles in Step S54 becomes 0.6 to 0.7, and the coating material 4 shrinks along with the change in state from the sol to the wet gel.

When the wet gel in Step S54 is dried at 100° C., a metal oxide in a dry gel form is generated (Step S55). The reaction formula and example are as illustrated in a column of the reaction formula and a column of the example in Step S55 of FIG. 6, respectively, which are similar to the reaction formula and example in Step S54.

Here, the volume of the dry gel made of aggregated particles in Step S55 is 0.5 to 0.6, and the coating material 4 shrinks along with the state in change from the wet gel to the dry gel.

When the dry gel in Step S55 is sintered at 300° C., a solid metal oxide, i.e., glass is generated (Step S56). The reaction formula and example are as illustrated in a column of the reaction formula and a column of the example in Step S56 of FIG. 6, respectively, which are similar to the reaction formulae and examples in Steps S54 and S55.

Here, the volume of the solid in Step S56 becomes 0.3 to 0.4, and the coating material 4 shrinks along with the change in state from the dry gel to the solid. Thus, the coating material 4 changes in state from the liquid, the sol, the wet gel, the dry gel, to the solid, and shrinks so that the volume thereof becomes about 30% to 40%. It is considered that the shrinking during the change in state from the dry gel to the solid contributes to the bonding method of the present invention.

The coating material may be supplied to the substrate in any stage between Steps S51 and S53 in which the coating material is in a liquid state. The stage in which the coating material is supplied can be selected depending upon the supply method.

As described above, according to the lighting devices of Embodiments 1 and 2, the bumps provided on the light-emitting element 2 and the electrodes provided on the substrate 3 can be bonded to each other by allowing the coating material 4 to shrink. This makes it unnecessary to use a wire or an adhesive for bonding therebetween, which can shorten the step of mounting a lighting device. Further, the shrinking force of the coating material 4 acts on the bottom surface 14 of the concave portion formed on the substrate 3 so as to pull the light-emitting element 2. This ensures the bonding between the bumps provided on the light-emitting element 2 and the electrodes provided on the substrate 3, which can enhance the reliability of electrical connection. Further, the coating material 4 is glass, and hence the influence involved in light and heat generated from the light-emitting element 2 can be reduced compared with resin-based materials. Thus, the reliability as a lighting device can be enhanced. Further, it is not necessary to use a connection terminal for wire bonding on the light-emitting element, and hence a light-emission efficiency equal to that of flip-chip bonding can be ensured.

The present invention has been described above by way of embodiments. However, the present invention is not limited thereto, and can be modified variously within a range not deviating from the technical idea of the present invention. For example, the shapes of the light-emitting element 2, the substrate 3, the bump, the adhesive 7, and the stoppers 15 and 16 are not limited.

What is claimed is:

1. A lighting device, comprising:
a substrate with an electrode formed thereon;
a light-emitting element having an electrode;
a conductive member that electrically connects the electrode of the substrate to the electrode of the light-emitting element; and
a coating material provided so as to protect a connection between the light-emitting element and the substrate,
wherein the coating material comprises a solid material obtained by curing a raw material containing one of metal alkoxide and polymetalloxane.

2. A lighting device according to claim 1, wherein the coating material is made of a solid material obtained by curing polymetalloxane generated from metal alkoxide.

3. A lighting device according to claim 1, wherein the light-emitting element is placed on a bottom surface of a concave portion formed on the substrate, and the coating material is supplied to the concave portion.

4. A lighting device according to claim 1, wherein the coating material is also placed in a gap between the substrate and the light-emitting element, and bonding between the conductive member and at least one of the electrode of the substrate and the electrode of the light-emitting element is kept by shrinking occurring when the raw material of the coating material is cured.

5. A lighting device according to claim 4, wherein the gap between the light-emitting element and the substrate includes an insulating adhesive with elasticity in a part thereof, and the coating material is placed in a portion without the insulating adhesive.

6. A lighting device according to claim 3, wherein the substrate includes a stopper formed thereon for positioning the light-emitting element at a predetermined place.

7. A lighting device according to claim 6, wherein the conductive member comprises a bump formed on the electrode of the light-emitting element.

8. A lighting device according to claim 1, wherein the electrode formed on the substrate comprises a through electrode passing through the substrate.

9. A lighting device according to claim 1, wherein the substrate is made of a glass material.

10. A production method for a lighting device in which an electrode formed on a substrate and an electrode formed on a light-emitting element are electrically connected to each other via a conductive member, the method comprising:
a first step of positioning the electrode of the substrate and the electrode of the light-emitting element each other, and fixing the light-emitting element to the substrate;
a second step of supplying a coating material containing one of metal alkoxide and polymetalloxane to a gap between the light-emitting element and the substrate; and
a third step of curing the coating material to generate a solid coating material,
wherein bonding between the conductive member and at least one of the electrode of the substrate and the electrode of the light-emitting element is kept by shrinking occurring when the coating material is cured.

11. A production method for a lighting device according to claim 10, wherein the third step includes curing polymetalloxane generated from metal alkoxide to generate a solid coating material.

12. A production method for a lighting device according to claim 10, wherein the third step includes further polycondensing and heat-curing polymetalloxane obtained by hydrolyzing and polycondensing metal alkoxide and water to generate a solid coating material.

13. A production method for a lighting device according to claim 10, wherein the first step includes firmly fixing the light-emitting element to the substrate with an insulating adhesive with elasticity.

14. A production method for a lighting device according to claim 10, further comprising a step of forming a stopper for positioning the light-emitting element at a predetermined place on the substrate,
wherein the first step includes positioning the light-emitting element to be fixed on the substrate by the stopper.
